(19) United States
(12) Patent Application Publication
(10) Pub. No.: US 2012/0075794 A1
(43) Pub. Date: Mar. 29, 2012

(54) CONTAINER DATA CENTER WITH POWER SUPPLY SYSTEM

(75) Inventors: CHAO-KE WEI, Tu-Cheng (TW); YAO-TING CHANG, Tu-Cheng (TW)

(73) Assignee: HON HAI PRECISION INDUSTRY CO., LTD., Tu-Cheng (TW)

(21) Appl. No.: 12/912,766

(22) Filed: Oct. 27, 2010

(30) Foreign Application Priority Data
Sep. 28, 2010 (TW) 99132901

(51) Int. Cl. H05K 7/20

(52) U.S. Cl. 361/679.48

(57) ABSTRACT

A container data center includes a power storage device, a power distribution device, a number of server systems, a portable container, and a number of power supply systems each connected between two opposite server systems in two rows. The power supply system includes a blower, a number of wind turbines, and a generator. Cooled air is blown to rotate the wind turbines by the blower, to generate mechanical energy. The generator receives the mechanical energy from the wind turbines and converts the received mechanical energy to electricity, and provides the converted electricity to the power storage device or the power distribution device.

### BACKGROUND

1. Technical Field

The present disclosure relates to a container data center having a power supply system.

2. Description of Related Art

With increasing heavy duty use of on-line applications, the need for computer data centers has increased rapidly. Data centers are centralized computing facilities that include many servers, often arranged in server racks or shelves, and one rack or shelf with some servers can be considered a server system. In a data center, some fans or blowers are arranged at appropriate locations to dissipate heat produced by the server systems.

Power supply systems of some container data centers convert main power to a certain voltage for the container data center. Therefore, there is opportunity to use airflows created by the heat dissipation system for other things.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic diagram of an exemplary embodiment of a container data center.

FIG. 2 is an interior, schematic view of the container data center of FIG. 1.

FIG. 3 is a block diagram of an embodiment of a power supply system used in the container data center of FIG. 1.

### DETAILED DESCRIPTION

The disclosure, including the drawings, is illustrated by way of example and not by limitation. It should be noted that references to “an” or “one” embodiment in this disclosure are not necessarily to the same embodiment, and such references mean at least one.

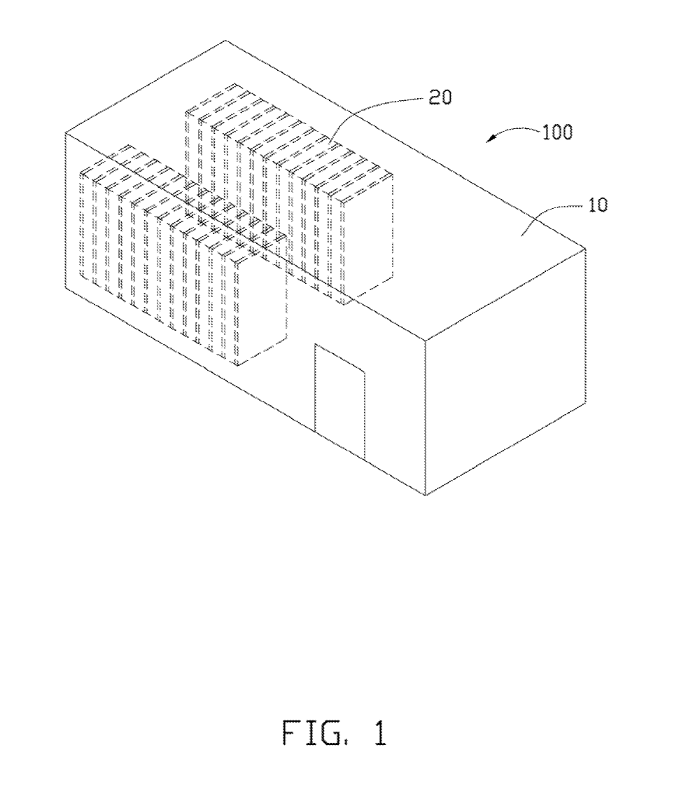

Referring to FIG. 1, an embodiment of a container data center 100 includes a power storage device 200, a power distribution device 300, a portable container 10, and a plurality of server systems 20 installed in the container 10. Each server system 20 includes a plurality of servers (not shown) stacked up. In one embodiment, the server systems 20 are arranged in two rows and the number of the server systems 20 is determined according to the size of the container 10. The container 10 includes a top wall 11, a bottom wall 12 opposite to the top wall 11, and two opposite sidewalls 13 connected between the top wall 11 and the bottom wall 12. A separating board 14 is arranged inside the container 10, adjacent to the bottom wall 12, thereby dividing the interior of the container 10 into a large first receiving space 15 to receive the server systems 20 and a small second receiving space 16. Two hot aisles 17 are formed between the two rows of server systems 20 and the corresponding sidewalls 13. Heat generated by the server systems 20 is dissipated into the air in the hot aisles 17. A cool aisle 18 is formed between the two rows of server systems 20.

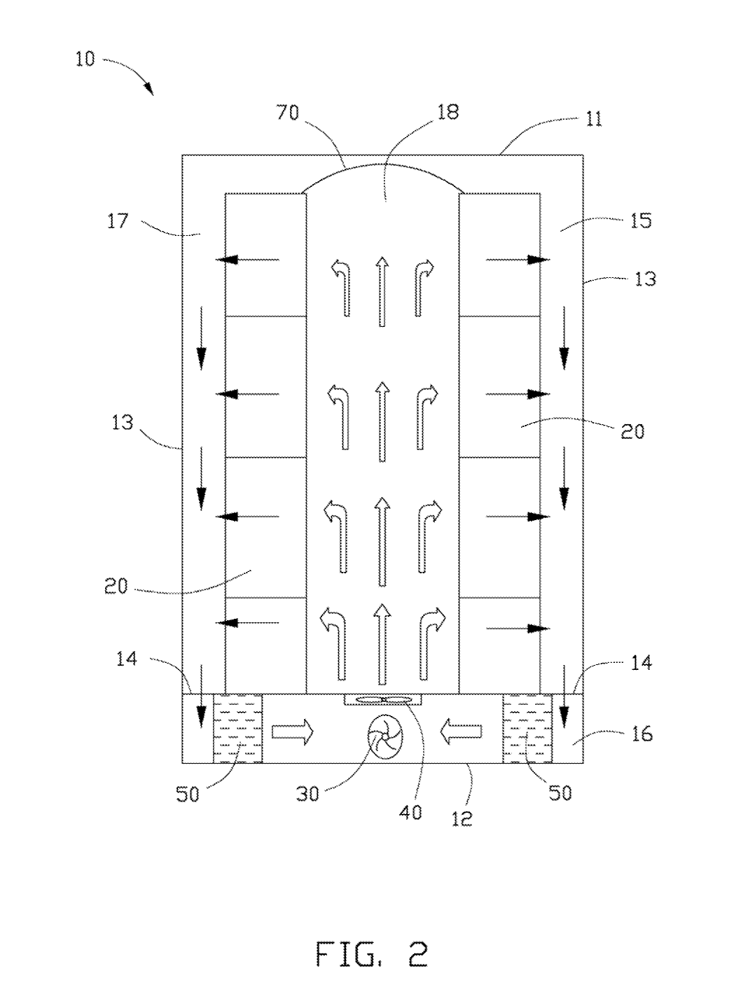

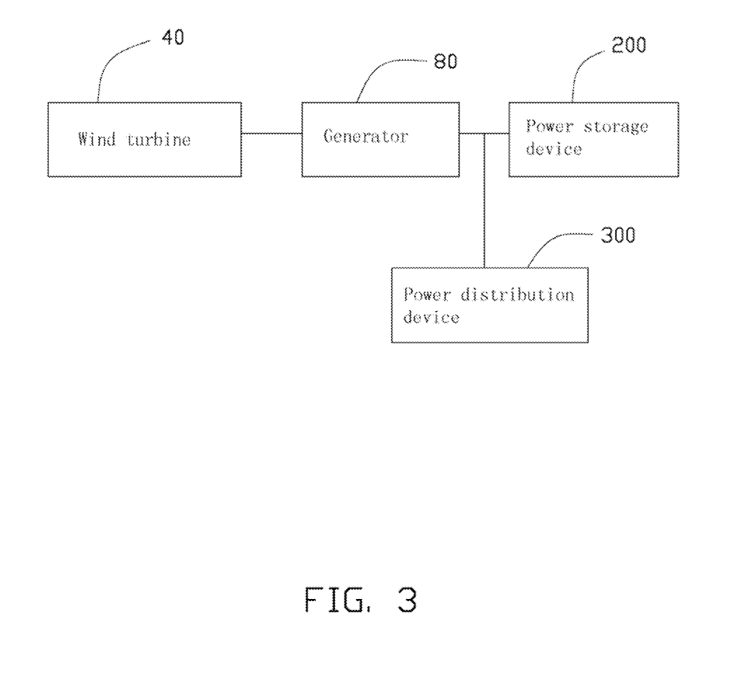

Referring to FIGS. 2 and 3, a plurality of power supply systems are respectively connected between each of two opposite server systems 20 in the two rows of the server systems 20. The power supply system includes a wind turbine 40, a generator 80, a blower 30, two heat exchangers 50 (such as cold water or cold medium), and a heat insulation board 70.

The blower 30 is arranged in a center of the second receiving space 16 and between the two rows of server systems 20, and blows upward. The heat exchangers 50 are accommodated in the second receiving space 16, respectively arranged below the two rows of server systems 20, and at opposite sides of the blower 30. The hot aisles 17 communicate with the parts of the second receiving space 16 at opposite sides of the heat exchangers 50. The cool aisle 18 communicates with the center part of the second receiving space 16 between the heat exchangers 50. The heat exchangers 50 are used to cool hot air from the hot aisles 17, and the cooled air is blown into the cool aisle 18 to dissipate heat of the server systems 20. The wind turbines 40 are located between the hot aisle 18 and the center part of the second receiving space 16. The heat insulation board 70 is connected to tops of the two rows of server systems 20, and covers a top of the cool aisle 18 to insulate the cool aisle 18 from the hot aisles 17.

Furthermore, the cooled air in the center part of the second receiving space 16 is blown to rotate the wind turbines 40 by the blower 30, to generate mechanical energy. The generator 80 receives the mechanical energy from the wind turbines 40 and converts the received mechanical energy to electricity, and provides the converted electricity to the power storage device 200 or the power distribution device 300 of the container data center 100. The power storage device 200 or the power distribution 300 provides the converted electricity to the container data center 100. Therefore, the power supply system of the container data center 100 can be supplemented by using energy of the cooling airflow, thereby saving electricity.

It is to be understood, however, that even though numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A container data center comprising:
a power storage device;
a power distribution device;
a plurality of server systems arranged in two rows;
a portable container comprising a top wall, a bottom wall opposite to the top wall, and two opposite sidewalls connected between the top wall and the bottom wall, a separating board is arranged inside the container, adjacent to the bottom wall, thereby dividing an inner space of the container into a large first receiving space to receive the plurality of server systems and a small second receiving space, two hot aisles formed between the two rows of server systems and the corresponding sidewalls, a cool aisle formed between the two rows of server systems; and
a plurality of power supply systems each connected between two opposite server systems in the two rows of server systems;
wherein each power supply system comprises a blower accommodated in a first part of the second receiving space below the cool aisle, a plurality of wind turbines arranged between the cool aisle and the first part of the second receiving space, and a generator, wherein the cooled air in the first part of the second receiving space is blown to rotate the plurality of wind turbines by the blower, to generate mechanical energy, the generator receives the mechanical energy from the plurality of wind turbines and converts the received mechanical energy to electricity, and provides the converted electricity to the power storage device or the power distribution device.

2. The container data center of claim 1, wherein each power supply system further comprises two heat exchangers accommodated in the second receiving space, respectively arranged below the two rows of server systems, and at opposite sides of the blower, the hot aisles communicate with second parts of the second receiving space at opposite sides of the heat exchangers, the cool aisle communicates with the first part of the second receiving space between the heat exchangers, the heat exchangers are used to cool hot air from the hot aisles, and the cooled air is blown into the cool aisle to dissipate heat of the server systems by the blower.

3. The data center of claim 2, wherein the heat insulation board is connected to tops of the two rows of server systems, and covers a top of the cool aisle to insulate the cool aisle from the hot aisles.

4. The container data center of claim 2, wherein the heat exchangers contain cold water or cold medium.
